(19) United States
(12) Patent Application Publication
(10) Pub. No.: US 2022/0149007 A1
(43) Pub. Date: May 12, 2022

(54) CHIP PACKAGING STRUCTURE AND METHOD

(71) Applicant: INSTITUTE OF SEMICONDUCTORS, GUANGDONG ACADEMY OF SCIENCES, Tianhe District, Guangzhou, Guangdong (CN)

(72) Inventors: Yuan BAO, Tianhe District, Guangzhou, Guangdong (CN); Xun XIANG, Tianhe District, Guangzhou, Guangdong (CN); Yao WANG, Tianhe District, Guangzhou, Guangdong (CN); Yingqiang YAN, Tianhe District, Guangzhou, Guangdong (CN); Chuan HU, Tianhe District, Guangzhou, Guangdong (CN); Zhitao CHEN, Tianhe District, Guangzhou, Guangdong (CN)

(21) Appl. No.: 17/047,731

(22) PCT Filed: Jun. 16, 2020
(86) PCT No.: PCT/CN2020/096347

§ 371 Date: Oct. 15, 2020

(51) Int. Cl. H01L 25/065; H01L 21/56; H01L 25/00

(52) U.S. Cl. CPC H01L 25/0657; H01L 21/568; H01L 2225/06586; H01L 2225/06541; H01L 2225/06548; H01L 25/50

(57) ABSTRACT

The present disclosure provides a chip packaging structure and method, using a back-to-back packaging structure, and realizing electrical connection between chips through TSV holes or cooperation between TSV and TMV holes, completely penetrating two chips. Thus, the TSV hole passing through a silicon material may not need to be formed in advance on the chips before bonding the chips, thereby the requirement of alignment accuracy of the chips can be reduced, and the process difficulty can be reduced. In addition, as the back-to-back packaging process is adopted, the heat dissipation efficiency of the chips can be improved, and the problem of circuit breakage due to materials with different expansion coefficients present between the chips can be avoided.

### TECHNICAL FIELD

The present disclosure relates to the technic field of semiconductors, in particular, to a chip packaging structure and method.

### BACKGROUND ART

With the miniaturization of electronic products, requirement to chip volumes of various electronic products is increasingly high. However, restricted to the bottleneck of the manufacturing process of the chip itself, currently, it becomes increasingly difficult to further reduce the volume of chips with the desire to meet chip performance. Therefore, new heterogeneous integrated chip packaging will become one of the important solutions for miniaturized electronic devices. The heterogeneous chip packaging is capable of packaging a plurality of dies or chiplets of different materials into a novel system-on-a-chip (SOC).

In the heterogeneous chip packaging technology, two-dimensional packaging is to arrange a plurality of chips on a same packaging substrate for packaging, that is, a plurality of chips are on one plane; while for the three-dimensional packaging, some chips may be overlaid for packaging, that is, some chips are not on the same plane. The three-dimensional packaging may render a smaller planar area than the two-dimensional packaging, but the difficulty of the three-dimensional packaging is also higher.

Currently, a three-dimensional integrated circuit packaging process mainly adopts the wafer-to-wafer packaging based on face-to-back (or front-to-back), and such packaging form is applicable to a wafer level packaging technology. However, this technology cannot achieve three-dimensional heterogeneous packaging of dies of different materials and types.

### SUMMARY

The present disclosure provides a chip packaging structure, including:

a first chip, wherein the first chip comprises a front surface and a back surface, the front surface of the first chip is a functional surface having a transistor, the back surface of the first chip is a non-functional surface, the front surface of the first chip comprises a plurality of pins, and the plurality of pins on the front surface of the first chip may be pins disposed on a first redistribution layer on the front surface of the first chip or pin pads directly formed on the front surface of the first chip;

a second chip, wherein the second chip comprises a front surface and a back surface, the front surface of the second chip is a functional surface, the back surface of the second chip is a non-functional surface, and the front surface of the second chip is provided with a second redistribution layer;

the back surface of the second chip is bonded to the back surface of the first chip;

an encapsulating material, wherein the encapsulating material wraps the first chip and the second chip;

a plurality of through holes, wherein the plurality of through holes include: a first through hole penetrating from a part of the pins on the front surface of the first chip to the second redistribution layer through the first chip and the second chip, and/or a second through hole penetrating from the first redistribution layer to the back surface of the second chip through the encapsulating material, and a third through-hole penetrating from the back surface of the second chip to the second redistribution layer through the second chip; and

the plurality of through holes are filled with a conductive material, and a part of the pins on the front surface of the first chip and/or the pins on the first redistribution layer are electrically connected with a part of the pins on the second redistribution layer through the conductive material.

The present disclosure further provides a chip packaging method, wherein the method comprises:

providing a first chip, wherein the first chip comprises a front surface and a back surface, the front surface of the first chip is a functional surface having a transistor, the back surface of the first chip is a non-functional surface, the front surface of the first chip comprises a plurality of pins, the plurality of pins on the front surface of the first chip are pins disposed on a first redistribution layer on the front surface of the first chip or pin pads directly formed on the front surface of the first chip;

providing a second chip, wherein the second chip comprises a front surface and a back surface, the front surface of the second chip is a functional surface, and the back surface of the second chip is a non-functional surface;

providing a temporary carrier board;

first bonding the front surface of the second chip to the temporary carrier board, and then bonding the back surface of the first chip to the back surface of the second chip, or first bonding the back surface of the first chip to the back surface of the second chip, and then bonding the front surface of the second chip to the temporary carrier board;

wrapping the first chip and the second chip with an encapsulating material, and removing the temporary carrier board;

forming, after forming the second redistribution layer on the front surface of the second chip, a first through hole penetrating from the second redistribution layer to a part of the pins on the front surface of the first chip and formed with an insulation layer and a conductive material; or forming, after forming the first through hole penetrating from the front surface of the second chip to a part of the pins on the front surface of the first chip and formed with the insulation layer and the conductive material, the second redistribution layer on the front surface of the second chip, so that a part of the pins on the front surface of the first chip are electrically connected with a part of the pins on the second redistribution layer through the conductive material in the first through hole; and

forming a pad layer and a solder ball on the second redistribution layer.

The present disclosure further provides a chip packaging method, wherein the method comprises:

providing a first chip, wherein the first chip comprises a front surface and a back surface, the front surface of the first chip is a functional surface having a transistor, the back surface of the first chip is a non-functional surface, the front surface of the first chip comprises a plurality of pins of pin pads directly formed on the front surface of the first chip;

providing a second chip, wherein the second chip comprises a front surface and a back surface, the front surface of the second chip is a functional surface, the back surface of the second chip is a non-functional surface, and a part of the region on the back surface of the second chip is formed with an intermediate redistribution layer;

providing a temporary carrier board;

first bonding the front surface of the second chip to the temporary carrier board, and then bonding the back surface of the first chip to the back surface of the second chip; or first bonding the back surface of the first chip to the back surface of the second chip, and then bonding the front surface of the second chip to the temporary carrier board;

wrapping the first chip and the second chip with an encapsulating material, and removing the temporary carrier board;

forming a first redistribution layer on the encapsulating material on the front surface of the first chip, forming a second redistribution layer on the front surface of the second chip, then forming a second through hole penetrating from the first redistribution layer to the intermediate redistribution layer through the encapsulating material and filled with the insulation layer and the conductive material, and forming a third through hole penetrating from the second redistribution layer to the intermediate redistribution layer and filled with the insulation layer and the conductive material; or first forming a second through hole penetrating from the first redistribution layer to the intermediate redistribution layer through the encapsulating material and filled with the insulation layer and the conductive material, and forming a third through hole penetrating from the second redistribution layer to the intermediate redistribution layer and filled with the insulation layer and the conductive material, then forming the first redistribution layer on the encapsulating material on the front surface of the first chip, and forming the second redistribution layer on the front surface of the second chip, so that a part of the pins on the first redistribution layer are electrically connected with a part of the pins on the second redistribution layer through the conductive material in the second through hole, the intermediate redistribution layer, and the conductive material in the third through hole; and

forming a pad layer and a solder ball on the second redistribution layer.

For the chip packaging structure and method provided in the present disclosure, in the solution provided in the present embodiment, before bonding the chips, a through silicon via TSV may not need to be formed in advance on the chips, therefore, the requirement to the alignment accuracy of the chips can be reduced, and the process difficulty can be reduced. In addition, as the back-to-back packaging process is adopted, the heat dissipation efficiency of the chips can be improved, and the problem of circuit breakage due to materials with different expansion coefficients present between the chips can be avoided.

### BRIEF DESCRIPTION OF DRAWINGS

In order to more clearly illustrate technical solutions of embodiments of the present disclosure, accompanying drawings which need to be used in the embodiments will be introduced briefly below, and it should be understood that the accompanying drawings below merely show some embodiments of the present disclosure, therefore, they should not be considered as limitation on the scope, and those ordinarily skilled in the art still could obtain other relevant accompanying drawings according to these accompanying drawings, without any inventive effort.

FIG. 1-FIG. 4 are schematic views of a chip packaging solution in the prior art;

FIGS. 5-10 are schematic views of a chip packaging structure provided in an embodiment of the present disclosure;

FIG. 11 is a schematic flowchart of steps of a chip packaging method provided in an embodiment of the present disclosure;

FIGS. 12-20 are schematic views of manufacturing principle of the chip packaging method provided in an embodiment of the present disclosure;

FIG. 21 is a first schematic flowchart of steps of a packaging manner for a third chip provided in an embodiment of the present disclosure;

FIG. 22 is a first schematic view of manufacturing principle of the packaging manner for the third chip provided in an embodiment of the present disclosure;

FIG. 23 is a second schematic flowchart of steps of the packaging manner for the third chip provided in an embodiment of the present disclosure;

FIGS. 24-25 are second schematic views of manufacturing principle of the packaging manner for the third chip provided in an embodiment of the present disclosure;

FIG. 26 is a schematic flowchart of steps of another chip packaging method provided in an embodiment of the present disclosure;

FIGS. 27-35 are schematic views of manufacturing principle of another chip packaging method provided in an embodiment of the present disclosure;

FIG. 36 is a third schematic flowchart of steps of the packaging manner for the third chip provided in an embodiment of the present disclosure;

FIG. 37 is a third schematic view of manufacturing principle of the packaging manner for the third chip provided in an embodiment of the present disclosure;

FIG. 38 is a fourth schematic flowchart of steps of the packaging manner for the third chip provided in an embodiment of the present disclosure; and

FIGS. 39-40 are fourth schematic views of manufacturing principle of the packaging manner for the third chip provided in an embodiment of the present disclosure.

### DETAILED DESCRIPTION OF EMBODIMENTS

In order to make objects, technical solutions and advantages of the embodiments of the present disclosure clearer, the technical solutions in the embodiments of the present disclosure will be described clearly and completely below in conjunction with accompanying drawings in the embodiments of the present disclosure, and apparently, the embodiments described are some but not all embodiments of the present disclosure. Generally, components in the embodiments of the present disclosure, as described and shown in the accompanying drawings herein, may be arranged and designed in various different configurations.

Therefore, the following detailed description of the embodiments of the present disclosure provided in the accompanying drawings is not intended to limit the scope of the present disclosure claimed, but merely represents chosen embodiments of the present disclosure. All of other embodiments obtained by those ordinarily skilled in the art based on the embodiments of the present disclosure without any inventive effort shall fall within the scope of protection of the present disclosure.

It should be noted that similar numerals and letters represent similar items in the following accompanying drawings, therefore, once a certain item is defined in one accompanying drawing, it is not needed to be further defined or explained in subsequent accompanying drawings.

In the description of the present disclosure, it should be indicated that orientation or positional relationships indicated by terms such as “center”, “upper”, “lower”, “left”, “right”, “vertical”, “horizontal”, “inner”, and “outer” are based on orientation or positional relationships as shown in the accompanying drawings, or orientation or positional relationships of a product of the present disclosure conventionally placed when in use, merely for facilitating describing the present disclosure and simplifying the description, rather than indicating or suggesting that related devices or elements have to be in the specific orientation, or configured or operated in a specific orientation, therefore, they should not be construed as limiting the present disclosure. Besides, terms such as “first”, “second”, and “third” are merely for distinctive description, but should not be construed as indicating or implying relative importance.

Moreover, terms such as “horizontal”, “vertical”, and “pendulous” do not mean that a component is required to be absolutely horizontal or pendulous, but mean that the component can be slightly inclined. For example, by “horizontal” it merely means that a structure is more horizontal in comparison with “vertical”, rather than being completely horizontal, while the structure can be slightly inclined.

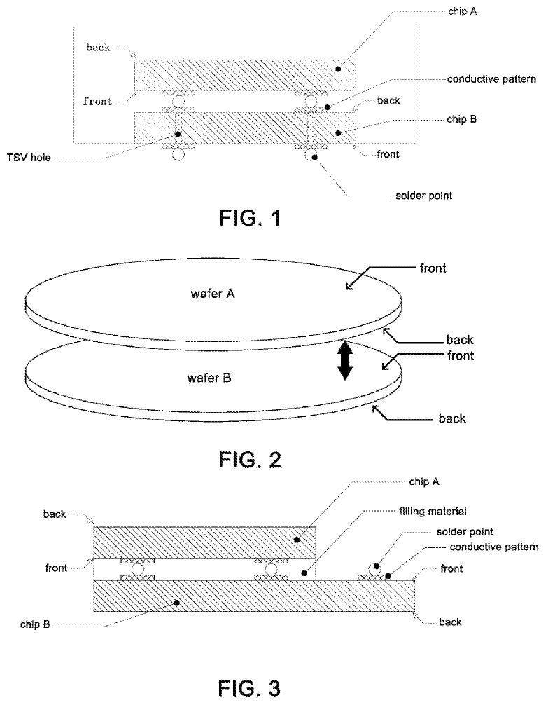

In some existing three-dimensional packaging technologies, a face-to-back packaging structure is commonly used. Referring to FIG. 1, in such a packaging structure, a front surface (a face having a pin or a redistribution layer) of a chip A and a front surface of a chip B are oriented to the same direction, a conductive pattern is prepared in advance on a back surface of the chip B and the chip B is formed with a TSV hole in advance, and the conductive pattern on the back surface of the chip B electrically communicates with a pin on the front surface of the chip B through a conductive material filled in the TSV hole. Then, the front surface of the chip A and the back surface of the chip B are bonded, so that the pin of the chip A is in electrical contact with the conductive pattern on the back surface of the chip B. The chip A and the chip B are then wrapped with an encapsulating material.

Such face-to-back packaging structure is generally applicable to wafer-level packaging, for example, referring to FIG. 2, in the manufacturing process, corresponding conductive patterns and through silicon vias (TSV) are first fabricated on a wafer A and a wafer B, and then the two wafers are accurately aligned and bonded together, so that conductive portions of corresponding chips on the two wafers are accurately bonded. Therefore, such packaging technology is suitable for wafers of the same type or even wafers made by the same manufacturing process, for example, two wafers are both DRAM memories, and the area and physical characteristics of each chip are consistent. If two wafers with different chip areas are heterogeneously integrated, it is difficult to accurately align the chip on the wafer A and the chip on the wafer B, therefore, this technology is not suitable for three-dimensional heterogeneous integration.

In some other existing three-dimensional packaging technologies, a face-to-face packaging structure is also adopted. Referring to FIG. 3, in the face-to-face packaging process, the front surface of the chip A faces the front surface of the chip B, and the redistribution layer (or pin) on the front surface of the chip A is electrically connected with the redistribution layer (or pin) on the front surface of the chip B by soldering tin. Such manner can realize the connection between circuits on the front surfaces of the chip A and the chip B without the TSV hole, and a filling material is filled between two dies so as to prevent short-circuiting. Remaining interfaces are led out by a solder joint from a position where the two dies do not overlap.

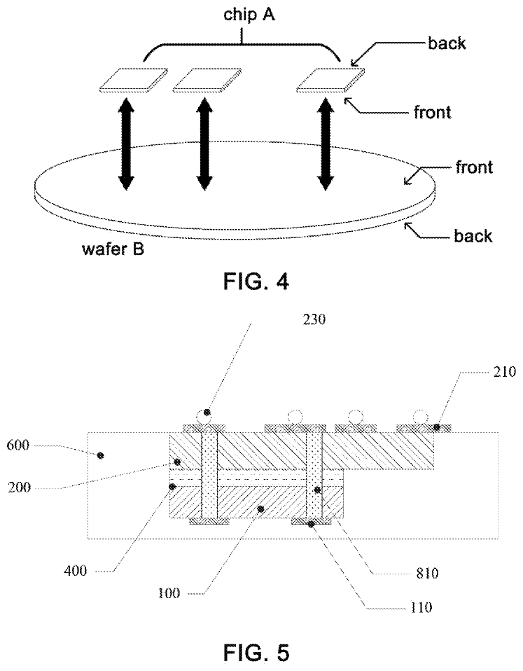

Such face-to-face packaging structure is generally applicable to die-to-die packaging process or die-to-wafer packaging process. For example, referring to FIG. 4, a plurality of chips A faces the front surface of the wafer B including a plurality of chips B, and then the plurality of chips A are correspondingly bonded to the wafer B.

The face-to-face packaging structure still has very high positioning requirement to relative positions of the chips and the wafer. In addition, since the circuit positions of two chips are quite close in distance, if the circuit power consumption is very high, the heat dissipation problem will be hard to solve. If the heat dissipation is relatively poor, and if the filling material between the chip A and the chip B and the soldering tin have different coefficients of thermal expansion, the circuit may be broken. Meanwhile, such packaging will consume the area of the pin led out of the chip, thereby causing too high density of distribution of the pin and leading to crosstalk and integrity problems of electrical signals.

Based on research on the above problems, the present embodiment provides a three-dimensional heterogeneous packaging structure and method with more efficient heat dissipation and more flexible packaging mode. The solutions provided in the embodiment are described in detail below.

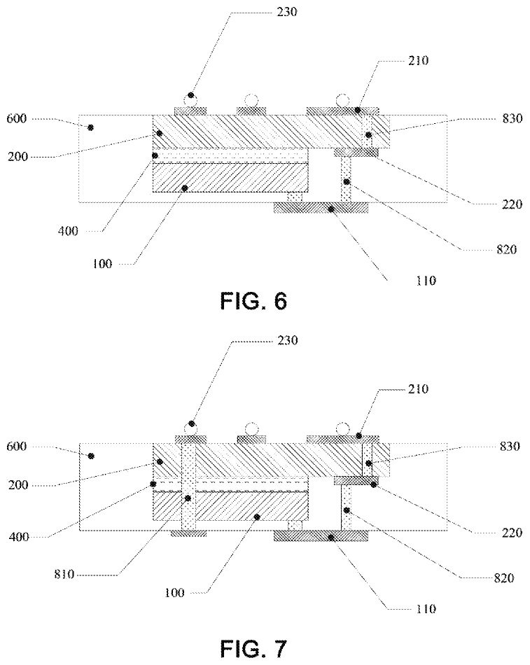

Referring to FIG. 5 and FIG. 6, the present disclosure provides a chip packaging structure in the form of back-to-back, and this chip packaging structure mainly includes a first chip 100, a second chip 200, an encapsulating material 600, a plurality of through holes and a conductive material in the through holes.

The first chip 100 includes a front surface and a back surface, the front surface of the first chip 100 is a functional surface having a transistor(s), and the back surface of the first chip 100 is a non-functional surface. The front surface of the first chip 100 includes a plurality of pins, and the plurality of pins on the front surface of the first chip 100 may be pin pads directly formed on the front surface of the first chip 100, as shown in FIG. 5; and the plurality of pins on the front surface of the first chip 100 may also be pins disposed on a first redistribution layer 110 on the front surface of the first chip 100, as shown in FIG. 6.

The second chip 200 includes a front surface and a back surface, the front surface of the second chip 200 is a functional surface, the back surface of the second chip 200 is a non-functional surface, and the front surface of the second chip 200 is provided with a second redistribution layer 210. In the above, the front surface of the second chip 200 may be provided with an insulation material layer, and the second redistribution layer 210 is formed on the insulation material layer, and is electrically connected with pins on the second chip 200 through via holes on the insulation material layer.

In the present embodiment, the back surface of the second chip 200 is bonded to the back surface of the first chip 100. In a possible implementation, the back surface of the first chip 100 and the back surface of the second chip 200 may be bonded together by a binding material 400. In another possible implementation, the back surfaces of the first chip 100 and the second chip 200 may be made of the same material, such as metal copper, silicon, silicon dioxide. The back surface of the first chip 100 and the back surface of the second chip 200 are directly bonded together by grinding them to a certain degree of smoothness, and as the back surfaces of the two chips are of the same material and have a relatively high degree of smoothness, the back surfaces of the two chips can be bonded together through an interaction force between molecules of the same material.

Compared with the solution in which the filling material between the two chips and the soldering tin has different coefficients of thermal expansion in the face-to-face packaging, in the back-to-back packaging manner adopted in the present embodiment, there are substantially no substances with different expansion coefficients between the two bonded chips, thereby circuit breakage due to different expansion coefficients may be effectively avoided when the temperature is relatively high.

The encapsulating material 600 wraps the first chip 100 and the second chip 200. In the above, the encapsulating material 600 is a dielectric material, such as epoxy resin.

Referring again to FIG. 5, in a possible implementation, the plurality of through holes include first through holes 810 penetrating from a part of the pins on the front surface of the first chip 100 to the second redistribution layer 210 through the first chip 100 and the second chip 200. That is, the first through hole 810 is a TSV hole.

Referring again to FIG. 6, in another possible implementation, the plurality of through holes include second through holes 820 penetrating from the first redistribution layer 110 to the back surface of the second chip 200 through the encapsulating material 600 and third through-holes 830 penetrating from the back surface of the second chip 200 to the second redistribution layer 210 through the second chip 200. That is, the second through hole 820 is a through molding via (TMV) passing through the encapsulating material 600, and the third through hole 830 is a through silicon via TSV.

The plurality of through holes are filled with a conductive material, and a part of the pins on the front surface of the first chip 100 and/or the pins on the first redistribution layer 110 are electrically connected with a part of the pins on the second redistribution layer 210 through the conductive material.

It should be noted that, in the present embodiment, an insulation layer is formed on an inner wall of the through holes penetrating the first chip 100 or the second chip 200, and the insulation layer electrically isolates the conductive material in the through holes from the first chip 100 or the second chip 200. In other words, in the present embodiment, in the plurality of through holes, an insulation layer is formed on the inner wall of the TSV hole.

It should also be noted that, in the chip packaging structure provided in the present embodiment, the number of the first through holes 810, the second through holes 820, and the third through holes 830 is not limited to the number shown in FIG. 5 and FIG. 6. In addition, in the present embodiment, the chip packaging structure may have only the first through holes 810 (as shown in FIG. 5), or only the second through holes 820 and the third through holes 830 (as shown in FIG. 6), or may simultaneously have the first through holes 810, the second through holes 820 and the third through holes 830 (as shown in FIG. 7).

In the present embodiment, the second redistribution layer 210 on the second chip 200 may serve as a redistribution layer of the entire packaging structure, and the second redistribution layer 210 may further be provided thereon with a pad layer and solder balls 230 for connection with other electronic circuit structures.

Based on the above designs, in the solution provided in the present embodiment, before bonding the chips, the TSV hole may not need to be formed in advance on the chips, thereby reducing the requirement to the alignment accuracy of the chips, and reducing the process difficulty. In addition, as the back-to-back packaging process is adopted, the heat dissipation efficiency of the chips can be improved, and the problem of circuit IC breakage due to materials with different expansion coefficients present between the chips can be avoided.

Optionally, in some possible implementations, an area of the second redistribution layer 210 is greater than the front surface of the second chip 200, and/or an area of the first redistribution layer 110 is greater than the front surface of the first chip 100. In other words, in the present embodiment, at least one of the first chip 100 and the second chip 200 may adopt a fan-out packaging structure, and at least one of the first redistribution layer 110 and the second redistribution layer 210 may be a fan-out redistribution layer.

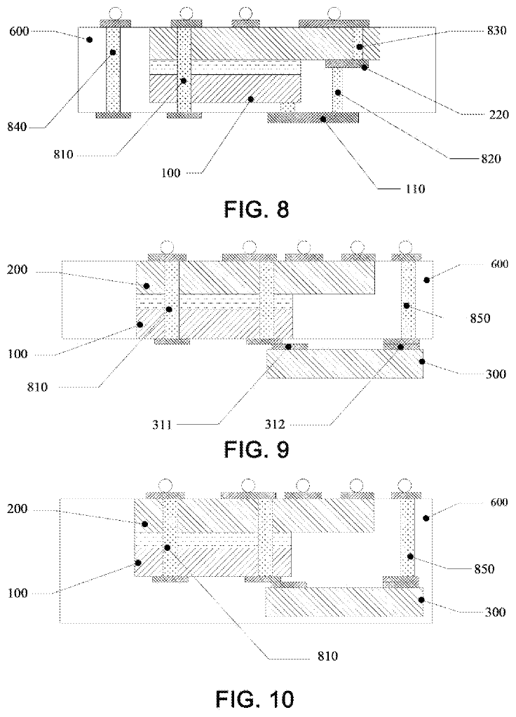

Optionally, referring to FIG. 8, in some possible implementations, the plurality of through holes of the chip packaging structure further include a fourth through hole(s) 840. The fourth through hole 840 penetrates from the first redistribution layer 110 to the second redistribution layer 210 through the encapsulating material 600, and the fourth through hole 840 is filled with a conductive material; a part of the pins on the first redistribution layer 110 are electrically connected with a part of the pins on the second redistribution layer 210 through the conductive material in the fourth through hole 840. In other words, in the present embodiment, the fourth through hole 840 is a TMV through hole, the pins on the first chip 100 can directly electrically communicate with the second redistribution layer 210, without passing through the first chip 100, through the conductive material filled in the fourth through hole 840.

Optionally, referring to FIG. 9, in some possible implementations, the chip packaging structure may further include a third chip 300.

A front surface of the third chip 300 is a functional surface, a back surface of the third chip 300 is a non-functional surface, the front surface of the third chip 300 includes a plurality of pins, the plurality of pins on the front surface of the third chip 300 may be pins disposed on a third redistribution layer 310 on the front surface of the third chip 300 or pin pads directly formed on the front surface of the third chip 300, and the front surface of the third chip 300 faces toward the front surface of the first chip 100.

In one example, a part of the pins (for example, a pin 311 shown in FIG. 9) on the front surface of the third chip 300 are electrically connected with a part of the pins on the front surface of the first chip 100 by a bonding material. In this way, electrical signal transmission between the third chip 300 and the first chip 100 can be realized.

In another example, a part of the pins on the front surface of the third chip 300 are corresponding to positions not covered by the second chip 200. The plurality of through holes further include a fifth through hole(s) 850, the fifth through hole 850 penetrates to a part of the pins on the front surface of the third chip 300 through the second chip 200 or the first chip 100, and the fifth through hole 850 is filled with the conductive material. In the above, a part of the pins on the second redistribution layer 210 are electrically connected with a part of the pins (a pin 312 as shown in FIG. 9) on the front surface of the third chip 300 through the conductive material in the fifth through hole 850. In this way, electrical signal transmission between the third chip 300 and the second redistribution layer 210 can be realized.

Based on the above design, in the solution provided in the present embodiment, in addition to the first chip 100 and the second chip 200, more chips may be stacked in the vertical direction, thereby further improving the integration degree of the chip packaging structure.

Further, in a possible implementation, the encapsulating material 600 may wrap only the first chip 100 and the second chip 200, but does not wrap the third chip 300, as shown in FIG. 9. In another possible implementation, referring to FIG. 10, the encapsulating material 600 may also wrap the third chip 300, and fill a gap between the third chip 300 and the first chip 100 and/or the second chip 200.

Optionally, in some implementations, the first redistribution layer 110 and/or the second redistribution layer 210 may be of a multi-layer redistribution layer structure, the multi-layer redistribution layer structure includes a plurality of sub-redistribution layers, and the plurality of sub-redistribution layers may transmit signals relatively independent of each other, and may be electrically connected to each other at certain positions.

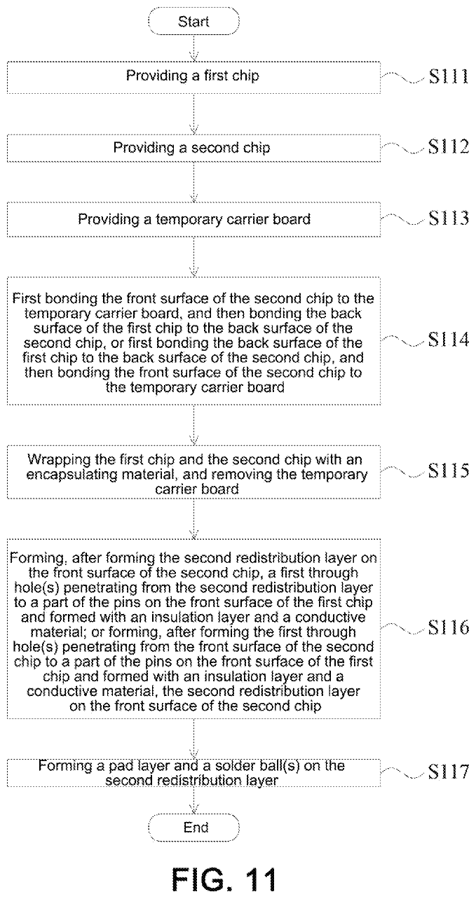

Referring to FIG. 11, FIG. 11 is a schematic flowchart of a chip packaging method provided in the present embodiment, and various steps of the method are explained in detail below.

Step S111: providing a first chip 100, wherein the first chip 100 includes a front surface and a back surface, the front surface of the first chip 100 is a functional surface having a transistor(s), the back surface of the first chip 100 is a non-functional surface, the front surface of the first chip 100 includes a plurality of pins, the plurality of pins on the front surface of the first chip 100 may be pins disposed on a first redistribution layer 110 on the front surface of the first chip 100 or pin pads directly formed on the front surface of the first chip 100.

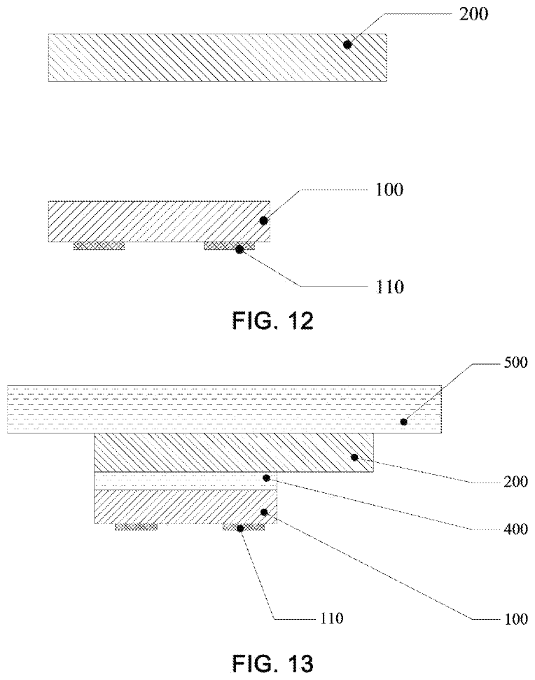

Referring to FIG. 12, in the present embodiment, the first chip 100 may be provided first, and a redistribution layer is formed on the front surface of the first chip 100, for example, a wafer on which the first chip 100 is located is fixed on a temporary carrier board 500 first, and the back surface of the wafer is connected with the carrier board. Then, a metal layer or a redistribution layer is fabricated and distributed on the front surface of the wafer. In the above, the redistribution layer may be a redistribution layer. The wafer is then cut to obtain a single such first chip 100.

Step S112, providing a second chip 200, wherein the second chip 200 includes a front surface and a back surface, the front surface of the second chip 200 is a functional surface, and the back surface of the second chip 200 is a non-functional surface.

Step S113, providing a temporary carrier board 500.

In the present embodiment, the temporary carrier board 500 in step S113 may be a glass carrier board.

Step S114: first bonding the front surface of the second chip 200 to the temporary carrier board 500, and then bonding the back surface of the first chip 100 to the back surface of the second chip 200; or first bonding the back surface of the first chip 100 to the back surface of the second chip 200, and then bonding the front surface of the second chip 200 to the temporary carrier board 500.

In the present embodiment, the back surface of the first chip 100 and the back surface of the second chip 200 can be bonded together by a binding material 400, as shown in FIG. 13.

Step S115, wrapping the first chip 100 and the second chip 200 with an encapsulating material 600, and removing the temporary carrier board 500.

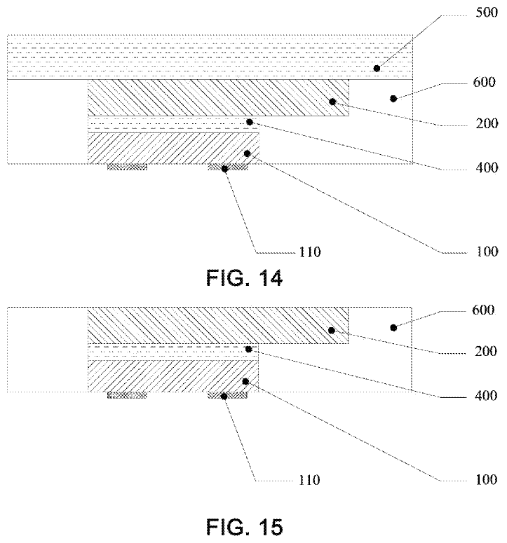

Referring to FIG. 14, in the present embodiment, the first chip 100 and the second chip 200 may be encapsulated with a dielectric material. After completing the encapsulation, the temporary carrier board 500 is removed, as shown in FIG. 15.

Step S116, forming, after forming the second redistribution layer 210 on the front surface of the second chip 200, first through holes 810 penetrating from the second redistribution layer 210 to a part of the pins on the front surface of the first chip 100 and filled with a conductive material; or forming, after forming the first through holes 810 penetrating from the front surface of the second chip 200 to a part of the pins on the front surface of the first chip 100 and filled with the conductive material, the second redistribution layer 210 on the front surface of the second chip 200, so that a part of the pins on the front surface of the first chip 100 are electrically connected with a part of the pins on the second redistribution layer 210 through the conductive material in the first through holes 810.

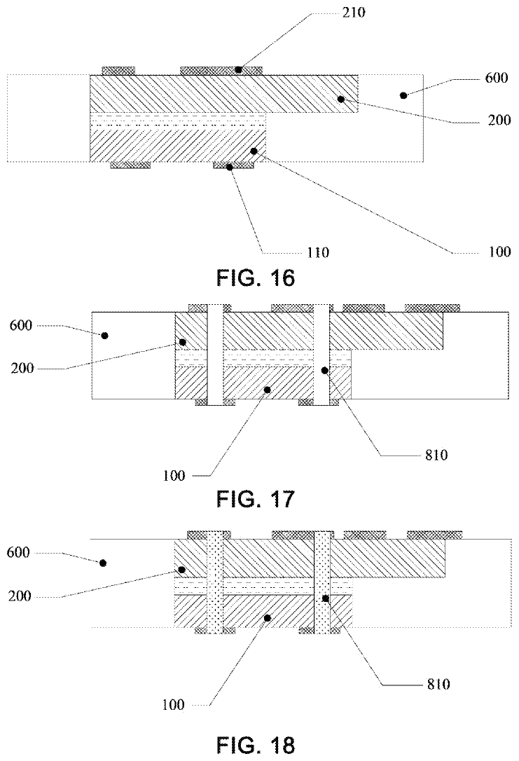

Optionally, in a first possible implementation, in step S116, the second redistribution layer 210 may be first formed on the front surface of the second chip 200, as shown in FIG. 16. Next, the first through holes 810 are formed, as shown in FIG. 17. Then, the first through hole 810 is filled with the conductive material, as shown in FIG. 18.

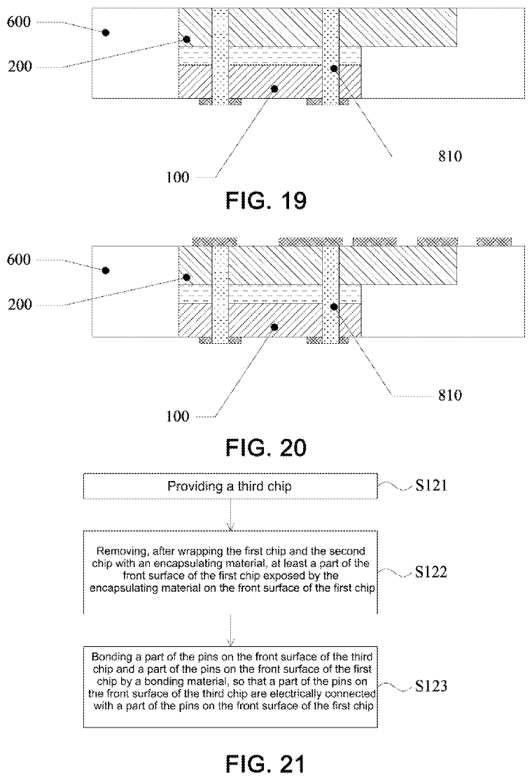

In a second possible implementation, in step S116, the first through holes 810 may be formed first and the conductive material is filled in the above first through holes 810, as shown in FIG. 19. Then, the second redistribution layer 210 is formed on the front surface of the second chip 200, as shown in FIG. 20.

It should be noted that, in the present embodiment, before filling the conductive material into the first through hole 810, an insulation material needs to be first covered on an inner wall of the through hole, and then the conductive material is filled into the first through hole 810, so as to prevent the conductive material from being in direct electrical contact with a silicon material inside the first chip 100 or the second chip 200.

Step S117, forming a pad layer and solder balls 230 on the second redistribution layer 210.

Optionally, in some other possible embodiments, it is also feasible that the second redistribution layer 210 is formed on the second chip 200 in advance, that is, the second chip 200 formed with the second redistribution layer 210 in advance is provided, and then steps such as bonding the two chips, forming the first through holes 810, and filling the conductive material are carried out.

Based on the above design, compared with the prior art solution in which TSV through holes need to be formed on the chips first, then the conductive patterns or solder points formed in advance are accurately aligned with the TSV through holes, in the chip packaging method provided in the present embodiment, it is feasible that the TSV through holes and the conductive patterns do not need to be formed in advance on the first chip 100 or the second chip 200, thus, the need for alignment accuracy of chips can be reduced, and the process difficulty is reduced.

Optionally, referring to FIG. 21, in some possible implementations, prior to step S117, step S121, step S122 and step S123 may be further included.

Step S121: providing a third chip 300, wherein the third chip 300 includes a front surface and a back surface, the front surface of the third chip 300 is a functional surface, the back surface of the third chip 300 is a non-functional surface, the front surface of the third chip 300 includes a plurality of pins, the plurality of pins on the front surface of the third chip 300 may be pins disposed on the third redistribution layer 310 on the front surface of the third chip 300 or pin pads directly formed on the front surface of the third chip 300.

Step S122, removing, after wrapping the first chip 100 and the second chip 200 with an encapsulating material 600, at least a part of the front surface of the first chip 100 exposed by the encapsulating material 600 on the front surface of the first chip 100.

Step S123, bonding a part of the pins on the front surface of the third chip 300 and a part of the pins on the front surface of the first chip 100 by a bonding material, so that a part of the pins on the front surface of the third chip 300 are electrically connected with a part of the pins on the front surface of the first chip 100.

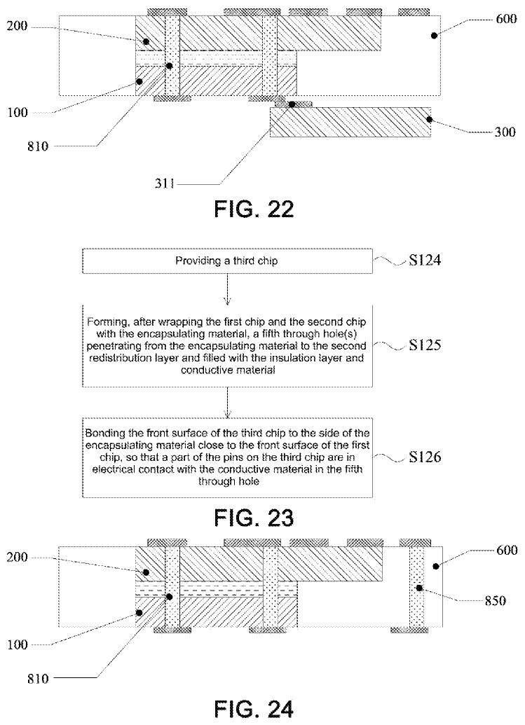

For example, referring to FIG. 22, in the present embodiment, the third redistribution layer 310 may include a pin 311 for electrical contact with the first redistribution layer 110, and in step S122, the pin 311 is electrically connected with a part of the pins on the first redistribution layer 110 by the bonding material.

Optionally, referring to FIG. 23, in some other possible implementations, prior to step S117, step S124, step S125 and step S126 may be further included.

Step S124: providing a third chip 300, wherein the third chip 300 includes a front surface and a back surface, the front surface of the third chip 300 is a functional surface, the back surface of the third chip 300 is a non-functional surface, the front surface of the third chip 300 includes a plurality of pins, the plurality of pins on the front surface of the third chip 300 may be pins disposed on the third redistribution layer 310 on the front surface of the third chip 300 or pin pads directly formed on the front surface of the third chip 300.

Step S125, forming, after wrapping the first chip 100 and the second chip 200 with the encapsulating material 600, a fifth through hole(s) 850 penetrating from the encapsulating material 600 to the second redistribution layer 210 and filled with the insulation layer and conductive material.

Step S126: bonding the front surface of the third chip 300 to the side of the encapsulating material 600 close to the front surface of the first chip 100, so that a part of the pins on the third chip 300 are in electrical contact with the conductive material in the fifth through hole 850, and accordingly a part of the pins on the front surface of the third chip 300 are electrically connected with a part of the pins on the second redistribution layer 210 through the conductive material in the fifth through hole 850.

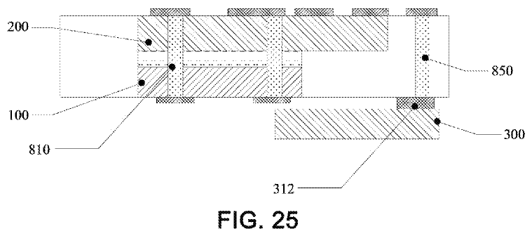

For example, in the present embodiment, the third redistribution layer 310 may include a pin 312 for electrical contact with the second redistribution layer 210. Referring to FIG. 24, in step S124, the formed fifth through hole 850 may be a TMV hole, and after the fifth through hole 850 is filled with the conductive material, a part of the region on the first redistribution layer 110 may be electrically connected with a part of the region on the second redistribution layer. Then in step S125, when bonding the third chip 300 to the front surface of the first chip 100, the pin 312 on the third chip 300 can be electrically connected with a part of the region on the second redistribution layer 210 through a part of the region on the first redistribution layer 110 and the conductive material in the fifth through hole 850, as shown in FIG. 25.

It should be noted that, in the present embodiment, the third chip 300 may only have the pin 311 or the pin 312, and may simultaneously have the pin 311 and the pin 312, as shown in FIG. 9.

Optionally, after bonding the third chip 300, the method may further include wrapping the third chip 300 with the encapsulating material 600.

Optionally, in the present embodiment, the method may further include forming a fourth through hole(s) 840 and filling the fourth through hole 840 with the conductive material, wherein the fourth through hole 840 penetrates from the first redistribution layer 110 to the second redistribution layer 210 through the encapsulating material 600, and a part of the pins on the first redistribution layer 110 are electrically connected with a part of the pins on the second redistribution layer 210 through the conductive material in the fourth through hole 840.

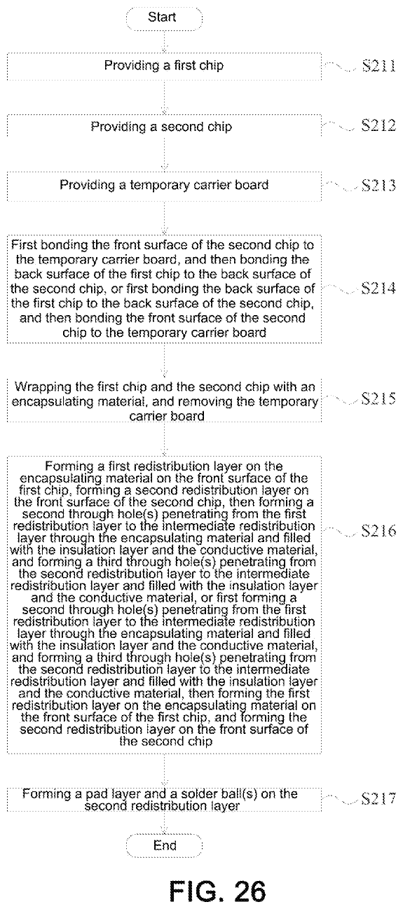

Referring to FIG. 26, FIG. 26 is a schematic flowchart of another chip packaging method provided in the present embodiment, and various steps of the method are explained in detail below.

Step S211: providing a first chip 100, wherein the first chip 100 includes a front surface and a back surface, the front surface of the first chip 100 is a functional surface having a transistor(s), the back surface of the first chip 100 is a non-functional surface, the front surface of the first chip 100 includes a plurality of pins of pin pads directly formed on the front surface of the first chip 100.

In the present embodiment, the first chip 100 may be provided first, and a redistribution layer is formed on the front surface of the first chip 100, for example, a wafer on which the first chip 100 is located is first fixed on a temporary carrier board 500, and a back surface of the wafer is connected with the carrier board. Then, a metal layer or a redistribution layer is fabricated and distributed on a front surface of the wafer. In the above, the redistribution layer may be a redistribution layer. The wafer is then cut to obtain a single such first chip 100.

Step S212, providing a second chip 200, wherein the second chip 200 includes a front surface and a back surface, the front surface of the second chip 200 is a functional surface, the back surface of the second chip 200 is a non-functional surface, and a part of the region on the back surface of the second chip 200 is formed with an intermediate redistribution layer 220.

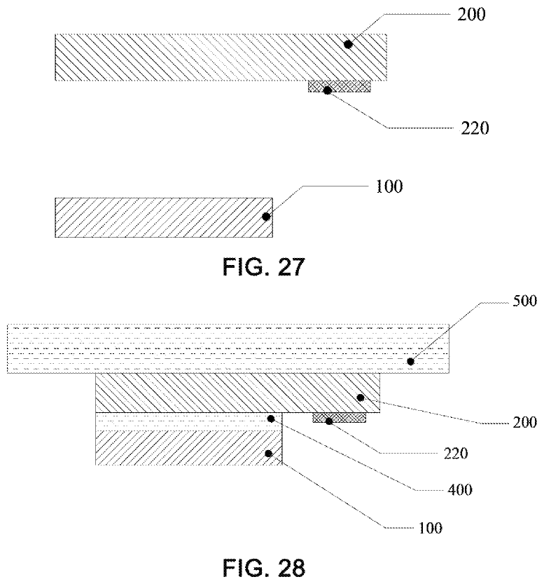

Referring to FIG. 27, in the present embodiment, the back surface of the second chip 200 may include a region that needs to be bonded to the first chip 100 and a region that does not need to be bonded to the first chip 100. In the above, the intermediate redistribution layer 220 may be formed on a region where the first chip 100 does not need to be bonded.

Step S213, providing a temporary carrier board 500.

Step S214: first bonding the front surface of the second chip 200 to the temporary carrier board 500, and then bonding the back surface of the first chip 100 to the back surface of the second chip 200; or first bonding the back surface of the first chip 100 to the back surface of the second chip 200, and then bonding the front surface of the second chip 200 to the temporary carrier board 500.

In the present embodiment, the back surface of the first chip 100 and the back surface of the second chip 200 can be bonded together by a binding material 400, as shown in FIG. 28.

Step S215, wrapping the first chip 100 and the second chip 200 with an encapsulating material 600, and removing the temporary carrier board 500.

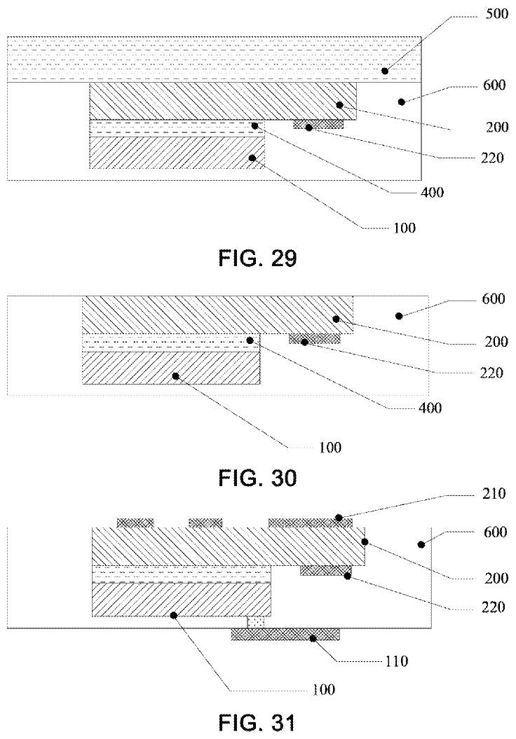

Referring to FIG. 29, in the present embodiment, the first chip 100 and the second chip 200 may be encapsulated with a dielectric material. After completing the encapsulation, the temporary carrier board 500 is removed, as shown in FIG. 30.

Step S216, forming a first redistribution layer 110 on the encapsulating material 600 on the front surface of the first chip 100, forming a second redistribution layer 210 on the front surface of the second chip 200, then forming a second through hole(s) 820 penetrating from the first redistribution layer 110 to the intermediate redistribution layer 220 through the encapsulating material 600 and filled with the insulation layer and the conductive material, and forming a third through hole(s) 830 penetrating from the second redistribution layer 210 to the intermediate redistribution layer 220 and filled with the insulation layer and the conductive material; or first forming a second through hole(s) 820 penetrating from the first redistribution layer 110 to the intermediate redistribution layer 220 through the encapsulating material 600 and filled with the insulation layer and the conductive material, and forming a third through hole(s) 830 penetrating from the second redistribution layer 210 to the intermediate redistribution layer 220 and filled with the insulation layer and the conductive material, then forming the first redistribution layer 110 on the encapsulating material 600 on the front surface of the first chip 100, and forming the second redistribution layer 210 on the front surface of the second chip 200, so that a part of the pins on the first redistribution layer 110 are electrically connected with a part of the pins on the second redistribution layer 210 through the conductive material in the second through hole 820, the intermediate redistribution layer 220, and the conductive material in the third through hole 830.

Optionally, in a first possible implementation, in step S216, the first redistribution layer 110 may be first formed on the encapsulating material 600 on the front surface of the first chip 100, and the second redistribution layer 210 may be formed on the front surface of the second chip 200, as shown in FIG. 31.

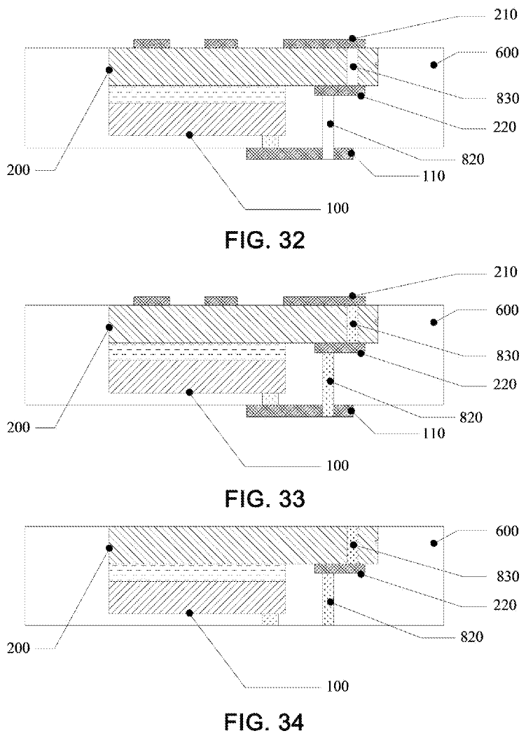

Then, a second through hole 820 penetrating from the first redistribution layer 110 to the intermediate redistribution layer 220 through the encapsulating material 600 and filled with the insulation layer and the conductive material is formed, and a third through hole 830 penetrating from the second redistribution layer 210 to the intermediate redistribution layer 220 and filled with the insulation layer and the conductive material is formed, as shown in FIG. 32.

Next, the conductive material is filled in the second through hole 820 and the third through hole 830, so that a part of the pins on the first redistribution layer 110 are electrically connected with a part of the pins on the second redistribution layer 210 through the conductive material in the second through hole 820, the intermediate redistribution layer 220, and the conductive material in the third through hole 830, as shown in FIG. 33.

Optionally, in a second possible implementation, in step S216, it is also feasible that the second through hole 820 penetrating from the first redistribution layer 110 to the intermediate redistribution layer 220 through the encapsulating material 600 and filled with the insulation layer and the conductive material is formed first, and the third through hole 830 penetrating from the second redistribution layer 210 to the intermediate redistribution layer 220 and filled with the insulation layer and the conductive material is formed, as shown in FIG. 34.

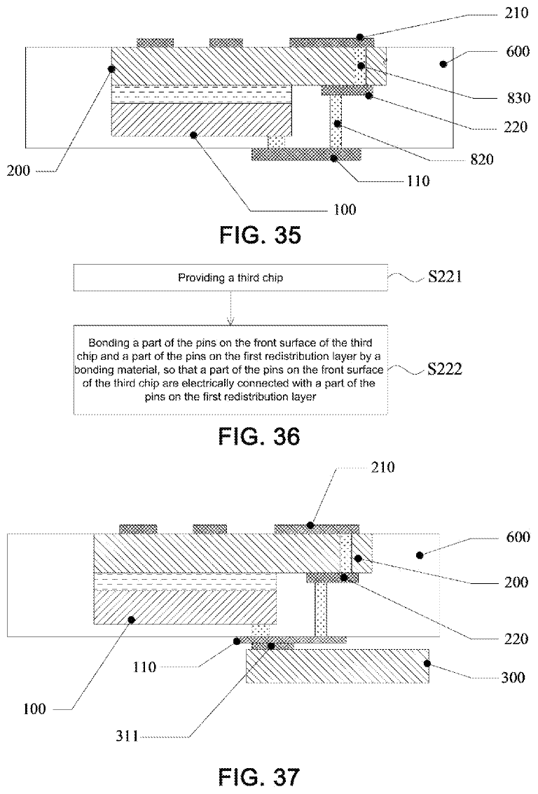

Then, a first redistribution layer 110 is formed on the encapsulating material 600 on the front surface of the first chip 100, and a second redistribution layer 210 is formed on the front surface of the second chip 200, so that a part of the pins on the first redistribution layer 110 are electrically connected with a part of the pins on the second redistribution layer 210 through the conductive material in the second through hole 820, the intermediate redistribution layer 220, and the conductive material in the third through hole 830, as shown in FIG. 35.

It should be noted that, in the present embodiment, before filling the conductive material into the third through hole 830, an insulation material needs to be first covered on an inner wall of the through hole, and then the conductive material is filled into the third through hole 830, so as to prevent the conductive material from being in direct electrical contact with a silicon material inside the second chip 200.

Step S217, forming a pad layer and solder balls 230 on the second redistribution layer 210.

Optionally, in some other possible embodiments, it is also feasible that the second redistribution layer 210 is formed on the second chip 200 in advance, that is, the second chip 200 formed with the second redistribution layer 210 in advance is provided, and then steps such as bonding the two chips, forming the second through hole 820 and the third through hole 830, and filling the conductive material are carried out.

Based on the above design, compared with the prior art solution in which TSV through holes need to be formed on the chips first, then the conductive patterns or solder points formed in advance are accurately aligned with the TSV through holes, in the chip packaging method provided in the present embodiment, it is feasible that the TSV through holes and the conductive patterns do not need to be formed in advance on the first chip 100 or the second chip 200, thus, the need for alignment accuracy of chips can be reduced, and the process difficulty is reduced.

Optionally, referring to FIG. 36, in some possible implementations, prior to step S217, step S221 and step S222 may be further included.

Step S221: providing a third chip 300, wherein the third chip 300 includes a front surface and a back surface, the front surface of the third chip 300 is a functional surface, the back surface of the third chip 300 is a non-functional surface, the front surface of the third chip 300 includes a plurality of pins, the plurality of pins on the front surface of the third chip 300 may be pins disposed on the third redistribution layer 310 on the front surface of the third chip 300 or pin pads directly formed on the front surface of the third chip 300.

Step S222, bonding a part of the pins on the front surface of the third chip 300 and a part of the pins on the first redistribution layer 110 by a bonding material, so that a part of the pins on the front surface of the third chip 300 are electrically connected with a part of the pins on the first redistribution layer 110.

For example, referring to FIG. 37, in the present embodiment, the third redistribution layer 310 may include a pin 311 for electrical contact with the first redistribution layer 110, and in step S222, the pin 311 is electrically connected with a part of the pins on the first redistribution layer by the bonding material.

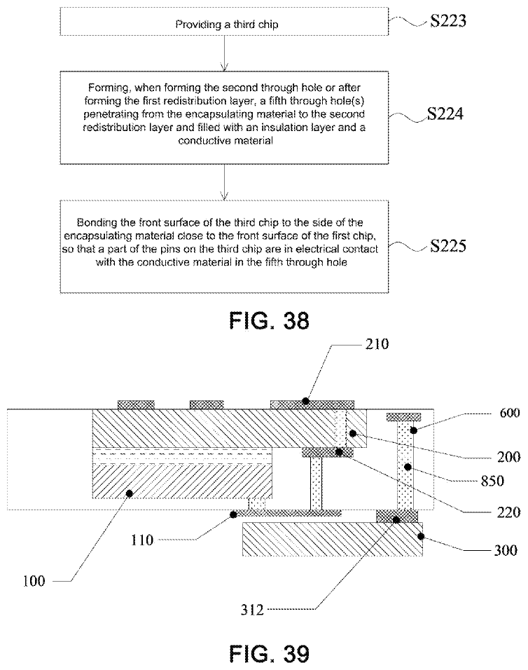

Optionally, referring to FIG. 38, in some other possible implementations, prior to step S217, step S223, step S224 and step S225 may be further included.

Step S223: providing a third chip 300, wherein the third chip 300 includes a front surface and a back surface, the front surface of the third chip 300 is a functional surface, the back surface of the third chip 300 is a non-functional surface, the front surface of the third chip 300 includes a plurality of pins, the plurality of pins on the front surface of the third chip 300 may be pins disposed on the third redistribution layer 310 on the front surface of the third chip 300 or pin pads directly formed on the front surface of the third chip 300.

Step S224, forming, when forming the second through hole 820 or after forming the first redistribution layer 110, a fifth through hole 850 penetrating from the encapsulating material 600 to the second redistribution layer 210 and filled with an insulation layer and a conductive material.

Step S225: bonding the front surface of the third chip 300 to the side of the encapsulating material 600 close to the front surface of the first chip 100, so that a part of the pins on the third chip 300 are in electrical contact with the conductive material in the fifth through hole 850, accordingly a part of the pins on the front surface of the third chip 300 are electrically connected with a part of the pins on the second redistribution layer 210 through the conductive material in the fifth through hole 850.

For example, in the present embodiment, the third redistribution layer 310 may include a pin 312 for electrical contact with the second redistribution layer 210. Referring to FIG. 39, in step S224, the formed fifth through hole 850 may be a TMV hole, and after the fifth through hole 850 is filled with the conductive material, a part of the region on the first redistribution layer 110 may be electrically connected with a part of the region on the second redistribution layer. Then in step S225, when bonding the third chip 300 to the front surface of the first chip 100, the pin 312 on the third chip 300 can be electrically connected with a part of the region on the second redistribution layer 210 through a part of the region on the first redistribution layer 110 and the conductive material in the fifth through hole 850.

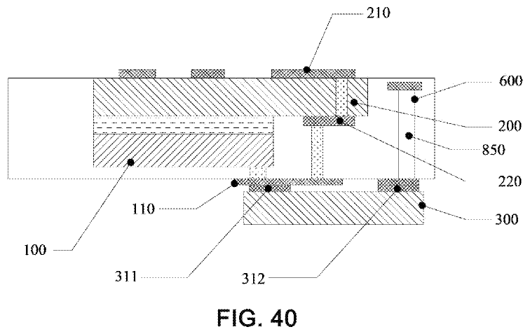

It should be noted that, in the present embodiment, the third chip 300 may only have the pin 311 or the pin 312, and also may have both the pin 311 and the pin 312, as shown in FIG. 40.

Optionally, after bonding the third chip 300, the method may further include wrapping the third chip 300 with the encapsulating material 600.

Optionally, in the present embodiment, the method may further include forming a fourth through hole 840 and filling the fourth through hole 840 with the conductive material, wherein the fourth through hole 840 penetrates from the first redistribution layer 110 to the second redistribution layer 210 through the encapsulating material 600, and a part of the pins on the first redistribution layer 110 are electrically connected with a part of the pins on the second redistribution layer 210 through the conductive material in the fourth through hole 840.

It should be indicated that herein, relational terms such as first and second are merely used for distinguishing one entity or operation from another entity or operation, while it is not necessarily required or implied that these entities or operations have any such practical relation or order. Moreover, terms “including”, “containing” or any other derivatives thereof are intended to be non-exclusive, thus a process, method, article or device including a series of elements not only include those elements, but also include other elements that are not listed definitely, or further include elements inherent to such process, method, article or device. Without more restrictions, an element defined with wordings “including a . . . ” does not exclude presence of other same elements in the process, method, article or device including said element.

The above-mentioned are merely various embodiments of the present disclosure, but the scope of protection of the present disclosure is not limited thereto, and any change or substitution that may easily occur to those skilled in the present art within the technical scope disclosed in the present disclosure should be covered within the scope of protection of the present disclosure. Therefore, the scope of protection of the present disclosure should be based on the scope of protection of the claims.

### INDUSTRIAL APPLICABILITY

For the chip packaging structure and method provided in the present disclosure, in the solutions provided in the present embodiment, the TSV hole passing through a silicon material may not need to be formed in advance on the chips before bonding the chips, thereby the requirement of alignment accuracy of the chips can be reduced, and the process difficulty can be reduced. In addition, as the back-to-back packaging process is adopted, the heat dissipation efficiency of the chips can be improved, and the problem of circuit breakage due to materials with different expansion coefficients present between the chips can be avoided.

1. A chip packaging structure, comprising:
a first chip, wherein the first chip comprises a front surface and a back surface, the front surface of the first chip is a functional surface having at least one transistor, the back surface of the first chip is a non-functional surface, the front surface of the first chip comprises a plurality of pins, and the plurality of pins on the front surface of the first chip are pins disposed on a first redistribution layer on the front surface of the first chip or pin pads directly formed on the front surface of the first chip;
a second chip, wherein the second chip comprises a front surface and a back surface, the front surface of the second chip is a functional surface, the back surface of the second chip is a non-functional surface, and the front surface of the second chip is provided with a second redistribution layer, wherein the back surface of the second chip is bonded to the back surface of the first chip;
an encapsulating material, wherein the encapsulating material wraps the first chip and the second chip; and
a plurality of through holes, wherein the plurality of through holes comprise at least one first through hole penetrating from a part of the plurality of pins on the front surface of the first chip to the second redistribution layer through the first chip and the second chip, and/or at least one second through hole penetrating from the first redistribution layer to the back surface of the second chip through the encapsulating material and at least one third through-hole penetrating from the back surface of the second chip to the second redistribution layer through the second chip, wherein
each of the plurality of through holes is filled with a conductive material, and a part of the plurality of pins on the front surface of the first chip and/or the pins on the first redistribution layer are electrically connected with a part of pins on the second redistribution layer through the conductive material.

2. The chip packaging structure according to claim 1, wherein
an area of the second redistribution layer is greater than that of the front surface of the second chip, and/or
an area of the first redistribution layer is greater than that of the front surface of the first chip.

3. The chip packaging structure according to claim 1, wherein the plurality of through holes further comprise at least one fourth through hole, and the at least one fourth through hole penetrates from the first redistribution layer to the second redistribution layer through the encapsulating material, and the at least one fourth through hole is filled with the conductive material; and
a part of the pins on the first redistribution layer are electrically connected with a part of the pins on the second redistribution layer through the conductive material in the at least one fourth through hole.

4. The chip packaging structure according to claim 1, wherein among the plurality of through holes, an insulation layer is formed on an inner wall of through holes penetrating the first chip or the second chip, wherein the insulation layer electrically isolates the conductive material in the through holes from the first chip or the second chip.

5. The chip packaging structure according to claim 1, wherein the back surface of the first chip and the back surface of the second chip are bonded to each other by a binding material.

6. The chip packaging structure according to claim 1, wherein the back surface of the first chip and the back surface of the second chip are made of a same material, and the back surface of the first chip and the back surface of the second chip are directly fixedly bonded after being ground.

7. The chip packaging structure according to claim 1, further comprising:
a third chip, wherein a front surface of the third chip is a functional surface, a back surface of the third chip is a non-functional surface, the front surface of the third chip comprises a plurality of pins, the plurality of pins on the front surface of the third chip are pins disposed on a third redistribution layer on the front surface of the third chip or pin pads directly formed on the front surface of the third chip; and the front surface of the third chip faces toward the front surface of the first chip, and a part of the plurality of pins on the front surface of the third chip are electrically connected with a part of the plurality of pins on the front surface of the first chip by a bonding material.

8. The chip packaging structure according to claim 1, further comprising:
a third chip, wherein a front surface of the third chip is a functional surface, a back surface of the third chip is a non-functional surface, the front surface of the third chip comprises a plurality of pins, the plurality of pins on the front surface of the third chip are pins disposed on a third redistribution layer on the front surface of the third chip or pin pads directly formed on the front surface of the third chip, and a part of the plurality of pins on the front surface of the third chip correspond to positions not covered by the second chip; and
the plurality of through holes further comprise at least one fifth through hole, wherein the at least one fifth through hole penetrates to a part of the plurality of pins on the front surface of the third chip through the second chip or the first chip, and the at least one fifth through hole is filled with the conductive material, wherein a part of the pins on the second redistribution layer are electrically connected with a part of the plurality of pins on the front surface of the third chip through the conductive material in the at least one fifth through hole.

9. The chip packaging structure according to claim 7 or 8, wherein the encapsulating material further wraps the third chip, and fills a gap between the third chip and the first chip and/or the second chip.

10. The chip packaging structure according to claim 1, wherein the first redistribution layer and/or the second redistribution layer are/is of a multi-layer redistribution layer structure, and the multi-layer redistribution layer structure comprises a plurality of sub-redistribution layers.

11. The chip packaging structure according to claim 1, further comprising:
a pad layer and at least one solder ball formed on the second redistribution layer.

12. A chip packaging method, wherein the method comprises:
providing a first chip, wherein the first chip comprises a front surface and a back surface, the front surface of the first chip is a functional surface having at least one transistor, the back surface of the first chip is a non-functional surface, the front surface of the first chip comprises a plurality of pins, the plurality of pins on the front surface of the first chip are pins disposed on a first redistribution layer on the front surface of the first chip or pin pads directly formed on the front surface of the first chip;
providing a second chip, wherein the second chip comprises a front surface and a back surface, the front surface of the second chip is a functional surface, and the back surface of the second chip is a non-functional surface;
providing a temporary carrier board;
bonding firstly the front surface of the second chip to the temporary carrier board, and then bonding the back surface of the first chip to the back surface of the second chip, or bonding firstly the back surface of the first chip to the back surface of the second chip, and then bonding the front surface of the second chip to the temporary carrier board;
wrapping the first chip and the second chip with an encapsulating material, and removing the temporary carrier board;
forming, after forming the second redistribution layer on the front surface of the second chip, at least one first through hole penetrating from the second redistribution layer to a part of the plurality of pins on the front surface of the first chip, in which the at least one first through hole is formed with an insulation layer and filled with a conductive material; or forming the second redistribution layer on the front surface of the second chip after forming the at least one first through hole penetrating from the front surface of the second chip to a part of the plurality of pins on the front surface of the first chip in which the at least one first through hole is formed with the insulation layer and filled with the conductive material, so that a part of the plurality of pins on the front surface of the first chip are electrically connected with a part of the pins on the second redistribution layer through the conductive material filled in the at least one first through hole; and
forming a pad layer and at least one solder ball on the second redistribution layer.

13. The chip packaging method according to claim 12, wherein prior to the forming a pad layer and at least one solder ball on the second redistribution layer, the method further comprises:
providing a third chip, wherein the third chip comprises a front surface and a back surface, the front surface of the third chip is a functional surface, the back surface of the third chip is a non-functional surface, the front surface of the third chip comprises a plurality of pins, the plurality of pins on the front surface of the third chip are pins disposed on a third redistribution layer on the front surface of the third chip or pin pads directly formed on the front surface of the third chip;
removing, after wrapping the first chip and the second chip with the encapsulating material, at least a part of the front surface of the first chip exposed by the encapsulating material on the front surface of the first chip; and
bonding a part of the plurality of pins on the front surface of the third chip and a part of the plurality of pins on the front surface of the first chip by a bonding material, so that a part of the plurality of pins on the front surface of the third chip are electrically connected with a part of the plurality of pins on the front surface of the first chip.

14. The chip packaging method according to claim 12, wherein prior to the forming a pad layer and at least one solder ball on the second redistribution layer, the method further comprises:
providing a third chip, wherein the third chip comprises a front surface and a back surface, the front surface of the third chip is a functional surface, the back surface of the third chip is a non-functional surface, the front surface of the third chip comprises a plurality of pins, the plurality of pins on the front surface of the third chip are pins disposed on the third redistribution layer on the front surface of the third chip or pin pads directly formed on the front surface of the third chip;
forming, after wrapping the first chip and the second chip with the encapsulating material, at least one fifth through hole penetrating from the encapsulating material to the second redistribution layer, in which the at least one fifth through hole is formed with the insulation layer and filled with the conductive material; and
bonding the front surface of the third chip to the side of the encapsulating material close to the front surface of the first chip, so that a part of the plurality of pins on the third chip are in electrical contact with the conductive material in the at least one fifth through hole, and accordingly a part of the plurality of pins on the front surface of the third chip are electrically connected with a part of the pins on the second redistribution layer through the conductive material in the at least one fifth through hole.

15. The chip packaging method according to claim 13, wherein the method further comprises:
wrapping the third chip with the encapsulating material.

16. A chip packaging method, wherein the method comprises:
providing a first chip, wherein the first chip comprises a front surface and a back surface, the front surface of the first chip is a functional surface having at least one transistor, the back surface of the first chip is a non-functional surface, the front surface of the first chip comprises a plurality of pins of pin pads directly formed on the front surface of the first chip;
providing a second chip, wherein the second chip comprises a front surface and a back surface, the front surface of the second chip is a functional surface, the back surface of the second chip is a non-functional surface, and a part of region on the back surface of the second chip is formed with an intermediate redistribution layer;
providing a temporary carrier board;
bonding firstly the front surface of the second chip to the temporary carrier board, and then bonding the back surface of the first chip to the back surface of the second chip; or bonding firstly the back surface of the first chip to the back surface of the second chip, and then bonding the front surface of the second chip to the temporary carrier board;
wrapping the first chip and the second chip with an encapsulating material, and removing the temporary carrier board;
forming a first redistribution layer on the encapsulating material on the front surface of the first chip, forming a second redistribution layer on the front surface of the second chip, then forming at least one second through hole penetrating from the first redistribution layer to the intermediate redistribution layer through the encapsulating material, in which the at least one second through hole is formed with a insulation layer and filled with a conductive material, and forming at least one third through hole penetrating from the second redistribution layer to the intermediate redistribution layer, in which the at least one third through hole is formed with the insulation layer and filled with the conductive material; or forming firstly at least one second through hole penetrating from the first redistribution layer to the intermediate redistribution layer through the encapsulating material, in which the at least one second through hole is formed with the insulation layer and filled with the conductive material, and forming at least one third through hole penetrating from the second redistribution layer to the intermediate redistribution layer, in which the at least one third through hole is formed with the insulation layer and filled with the conductive material, then forming the first redistribution layer on the encapsulating material on the front surface of the first chip, and forming the second redistribution layer on the front surface of the second chip, so that a part of pins on the first redistribution layer are electrically connected with a part of pins on the second redistribution layer through the conductive material in the at least one second through hole, the intermediate redistribution layer, and the conductive material in the at least one third through hole; and
forming a pad layer and at least one solder ball on the second redistribution layer.

17. The chip packaging method according to claim 16, wherein prior to the forming a pad layer and at least one solder ball on the second redistribution layer, the method further comprises:
providing a third chip, wherein the third chip comprises a front surface and a back surface, the front surface of the third chip is a functional surface, the back surface of the third chip is a non-functional surface, the front surface of the third chip comprises a plurality of pins, the plurality of pins on the front surface of the third chip are pins disposed on a third redistribution layer on the front surface of the third chip or pin pads directly formed on the front surface of the third chip; and
bonding a part of the plurality of pins on the front surface of the third chip and a part of the pins on the first redistribution layer by a bonding material, so that a part of the plurality of pins on the front surface of the third chip are electrically connected with a part of the pins on the first redistribution layer.

18. The chip packaging method according to claim 16, wherein prior to the forming a pad layer and at least one solder ball on the second redistribution layer, the method further comprises:
providing a third chip, wherein the third chip comprises a front surface and a back surface, the front surface of the third chip is a functional surface, the back surface of the third chip is a non-functional surface, the front surface of the third chip comprises a plurality of pins, the plurality of pins on the front surface of the third chip are pins disposed on a third redistribution layer on the front surface of the third chip or pin pads directly formed on the front surface of the third chip;
forming, when forming the at least one second through hole or after forming the first redistribution layer, at least one fifth through hole penetrating from the encapsulating material to the second redistribution layer, in which the at least one fifth through hole is formed with the insulation layer and filled with the conductive material; and
bonding the front surface of the third chip to the side of the encapsulating material close to the front surface of the first chip, so that a part of the plurality of pins on the third chip are in electrical contact with the conductive material in the at least one fifth through hole, and accordingly a part of the plurality of pins on the front surface of the third chip are electrically connected with a part of the pins on the second redistribution layer through the conductive material in the at least one fifth through hole.

19. The chip packaging method according to claim 17, wherein the method further comprises:
wrapping the third chip with the encapsulating material.

20. The chip packaging structure according to claim 8, wherein the encapsulating material further wraps the third chip, and fills a gap between the third chip and the first chip and/or the second chip.
